(19) United States
(12) Patent Application Publication
(10) Pub. No.: US 2017/0040966 A1
(43) Pub. Date: Feb. 9, 2017

(54) COMBINED IMPEDANCE MATCHING AND RF FILTER CIRCUIT

(71) Applicant: Epcos AG, München (DE)

(72) Inventors: Juha Ellä, Halikko (FI); Edgar Schmidhammer, Stein An Der Traun (DE)

(21) Appl. No.: 15/116,073

(22) PCT Filed: Jun. 5, 2014
(86) PCT No.: PCT/EP2014/061715

§ 371 Date: Aug. 2, 2016

(30) Foreign Application Priority Data
Feb. 28, 2014 (DE) 10 2014 102 704.3

(51) Int. Cl. H03H 7/01; H03H 7/46; H04B 1/40; H03F 3/189; H03F 3/20; H03H 9/54; H03H 7/38; H03F 1/56

(52) U.S. Cl. CPC H03H 7/0115; H03H 7/38; H03H 7/463; H03F 1/56; H03F 3/189; H03F 3/20; H03H 9/542; H04B 1/40; H03F 2200/387; H03F 2200/171; H03F 2200/294; H03F 2200/451

(57) ABSTRACT

What is specified is a combined impedance matching and RF filter circuit having improved impedance matching in conjunction with good frequency-tunability of the filter circuit. The circuit comprises a reactance elimination circuit for reducing the reactance and a tunable RF filter circuit, which is frequency-tunable and can carry out a resistance matching.

The invention relates to circuits which can be used in non-wired communication devices and can both perform an impedance matching and fulfill a filter function. The filter function also includes the adjustability of characteristic filter frequencies.

Portable communication devices require RF filters in order to separate desired signals from undesired signals. In this case it is necessary to fulfill requirements regarding selection, insertion loss, edge steepness, ripple in a passband and structural size. Since the speed of sound in a solid is generally significantly lower than the speed at which electromagnetic waves propagate, electroacoustic filters permit small dimensions in conjunction with at the same time good filter properties.

The ever increasing number of frequency bands which are intended to be able to be operated by a communication device would in principle require an ever increasing number of filters, which is not very desirable with regard to structural size, costs, susceptibility to faults, etc. Tunable filters, that is to say filters which can operate in a plurality of frequency bands by virtue of adjustable characteristic frequencies such as center frequencies and bandwidths, indeed exist, but entail new problems.

Previous configurations of tunable filters are essentially based on extending known filter circuits by tunable impedance elements, or on the use of switches that can be used to supplementarily connect filter elements with respect to a filter topology.

In this regard, the paper “Reconfigurable Multi-band SAW Filters For LTE Applications”, Xiao Ming et al., Power Amplifiers For Wireless And Radio Applications (PAWR), 2013 IEEE Topical Conference, Jan. 20, 2013, pages 82-84, discloses substantially conventional RF filters which are reconfigurable by means of switches. In this case, however, filters reconfigurable by means of switches do not enable continuously tunable duplexers.

The paper “Tunable Filters Using Wideband Elastic Resonators”, Kadota et al., IEEE Transactions on Ultrasonics, Ferroelectrics and Frequency Control, vol. 60, no. 10, October 2013, pages 2129-2136, discloses filter circuits in which tunable capacitors are added to RF filters with acoustic resonators.

The paper “A Novel Tunable Filter Enabling Both Center Frequency and Bandwidth Tunability”, Inoue et al., Proceedings Of The 42^{nd} European Microwave Conference, Oct. 29-Nov. 1, 2012, Amsterdam, the Netherlands, pages 269-272, discloses RF filters comprising tunable capacitors and tunable inductances.

The paper “RFMEMS-Based Tunable Filters”, Brank et al., 2001, John Wiley & Sons, Inc. Int. J. RF and Microwave CAE11: pages 276-284, 2001, also discloses interconnections of L and C elements, wherein the capacitances of the capacitive elements are adjustable.

The paper “Design of a Tunable Bandpass Filter With the Assistance of Modified Parallel Coupled Lines”, Tseng et al., 978-1-4673-2141-9/13/$31.00, 2013 IEEE, discloses tunable filters with coupled transmission lines.

The paper “Tunable Isolator Using Variable Capacitor for Multi-band System”, Wada et al., 978-1-4673-2141-9/13/$31.00, 2013 IEEE MTT-S Symposium, and the publication WO2012/020613 disclose the use of isolators in RF filters.

The paper “Filters with Single Transmission Zeros at Real or Imaginary Frequencies”, Levy, IEEE Transactions on Microwave Theory and Techniques, vol. MTT-24, no. 4, April 1976, discloses embodiments of various Chebyshev filters with coupled circuit elements.

The paper “Co-Design of Multi-Band High-Efficiency Power Amplifier and Three-Pole High-Q Tunable Filter”, K. Chen, T.-C. Lee, D. Peroulis, IEEE Microwave and Wireless Components Letters, Vol. 23, No. 12, December 2013, discloses the possibility of combining a tunable filter with an impedance transformation.

For the RF circuits known from the papers cited above it can be stated in summary that essentially known filter topologies by adding variable elements, e.g. switches or adjustable impedance elements, tunable filter circuits are obtained.

What is problematic about that is that the known filter topologies used are essentially optimized for the use of impedance elements having a constant impedance. Although tunable filters are made possible, the performance is detrimentally affected here by the tunability. Furthermore, the changes that enable the tunability cause increased difficulty of integration into an external circuit environment, since the impedance matching is impaired.

Furthermore, the constant desire remains for improved energy efficiency.

It is therefore an object to specify a filter circuit which is diversely usable as a result of a frequency-tunability, has good filter properties and operates energy-efficiently.

In this case, such a filter circuit is a combined impedance matching and RF filter circuit comprising a signal input and a signal output. The circuit furthermore comprises a reactance elimination circuit between the signal input and the signal output. Furthermore, the circuit comprises a frequency-tunable RF filter circuit interconnected in series with the reactance elimination circuit between the signal input and the signal output. The signal input and the signal output are in each case provided for being interconnected with circuit components having different connection impedances. The reactance elimination circuit makes available an output impedance without reactance. The tunable RF filter circuit is suitable for carrying out a matching of the resistance with unchanged reactance.

In other words, a filter circuit is specified which fulfills both an impedance matching functionality and a filter functionality. In this case, the filter functionality has a scope broad enough that characteristic filter frequencies such as a center frequency of a passband and/or the bandwidth of the passband are adjustable.

In this case, the filter effect of the circuit is primarily brought about by the RF filter circuit. The impedance matching functionality is brought about both by the reactance elimination circuit and by the RF filter circuit. In this case, the reactance elimination circuit is restricted to matching the reactance, that is to say the imaginary part of the impedance, while the tunable RF filter circuit carries out the matching of the resistance, that is to say of the real part of the impedance. The impedance matching carried out by the combined impedance matching and RF filter circuit is thus distributed between the two main constituents of the circuit.

Hereinafter, the term “circuit” in this case denotes the combined impedance matching and RF filter circuit. By means of the signal input of the circuit, the latter can be interconnected with a signal port of an external circuit environment, wherein the signal port has a first characteristic connection impedance. By means of its signal output, the circuit can be interconnected with a further signal port of the external circuit environment, wherein the further signal port has a second characteristic impedance. In the design of RF circuits, typically, care is taken to ensure that different circuit components have identical input and output impedances, such that a direct interconnection is possible. Such typical line impedances are for example 25Ω, 50Ω, or 100Ω.

However, there are circuit components, such as power amplifiers or low noise amplifiers, whose connection ports have impedances that deviate significantly from such typical impedances. In this regard, power amplifiers generally have signal outputs having a significantly lower impedance, while low noise amplifiers have signal inputs having a significantly higher input impedance. However, typical RF filters, e.g. bandpass filters operating with electroacoustic components, generally have characteristic input and output frequencies of 50Ω. Consequently, impedance matching networks are necessary in conventional RF circuits, which impedance matching networks interconnect the ports of the amplifiers with the ports of the filters or ports of the filters with antenna ports and reduce a reflection of RF signals as a result of their impedance matching.

In unconventional filter circuits whose characteristic filter frequencies are adjustable, for example, conventional concepts based on impedance matching circuits are encountering their limits since the input and/or output impedances of tunable filters vary upon a variation of the operating frequencies of the filters.

Despite an impedance matching network, therefore, a complete absence of reflected signals is not always obtained.

The advantage of the present circuit is, then, that a very good impedance matching can be obtained despite frequency-tunability of the filter effect since it has been recognized that a tunable RF filter circuit enables not only a tunable filter effect, but also adjustment of the resistance.

At the same time it has been recognized that an impedance matching network can be constructed particularly simply and, as a result, operates very energy-efficiently with a very low insertion loss if it only has to match the reactance. Therefore, a reactance elimination circuit was chosen as impedance matching network, said reactance elimination circuit reducing an input impedance to a real output impedance having a vanishing imaginary part. The combination of reactance elimination circuit and tunable RF filter circuit which can carry out a matching of the resistance therefore allows a very good impedance matching over a wide impedance range in conjunction with at the same time good adjustability of characteristic filter frequencies over a wide frequency range. In addition, such a circuit operates with comparatively low losses on account of the relatively small number of circuit components required.

It is possible for the tunable RF filter circuit to comprise a resistance matching circuit on the input and/or output side.

The tunable RF filter circuit is then also divided into circuit regions which respectively bring about the resistance matching and the filter functionality independently of one another and without being disturbed by the corresponding other region.

Particularly if the resistance matching circuit or a plurality of resistance matching circuits are arranged within the tunable RF filter circuit at the inputs and/or outputs thereof, that circuit region of the tunable RF filter circuit which is responsible for the actual filter functionality always sees an optimally matched impedance and can therefore operate without disturbance.

It is possible for the tunable RF filter circuit to comprise tunable capacitive and/or inductive elements for the frequency tuning.

In this case, tunable capacitive elements are preferred since they can be realized more easily. Such tunable capacitive elements can be formed for example by varactors or capacitance banks comprising individually switchable capacitance elements.

It is possible for the tunable RF filter circuit to be constructed from passive circuit elements. In this case, passive circuit elements are understood to be circuit elements such as capacitive elements, inductive elements, waveguides suitable for guiding electromagnetic signals, transmission lines, etc. As a result, the passive circuit elements are delimited from active circuit elements such as semiconductor components comprising transistors.

The use of electroacoustic components such as SAW components (SAW=Surface Acoustic Wave), BAW components (BAW=Bulk Acoustic Wave) or GBAW components (GBAW=Guided Bulk Acoustic Wave) in the tunable RF filter circuit is possible, but not absolutely necessary.

It is likewise possible for the reactance elimination circuit to comprise capacitive and/or inductive elements.

It is then possible for the reactance elimination circuit to comprise tunable capacitive and/or inductive elements for reducing the absolute value of the reactance. In this case, reducing the absolute value of the reactance explicitly includes—as also indicated by the name “reactance elimination circuit”—ideally completely or at least partly eliminating the reactance, i.e. the imaginary part of the impedance.

It is preferred here to reduce the absolute value of the reactance to the smallest possible value.

It is possible for the tunable RF filter circuit to comprise a filter core having a first signal route and a second signal route. In this case, the second signal route is arranged in parallel with the first signal route. A first impedance element, e.g. an inductive element or a capacitive element, is interconnected in the first signal route. Impedance elements that are interconnected in series and electromagnetically coupled to one another are arranged in the second signal route.

The tunable RF filter circuit comprises an input, an output and a signal path. The signal path is arranged between the input and the output and connects the input to the output, such that RF signals which are intended to pass through the filter circuit are conducted from the input to the output. For example, N≧3—that is to say three or more—resonant circuits are arranged one after another in the second signal route and in each case interconnect the second signal route with ground. Each resonant circuit thus represents as it were a shunt element, such that the resonant circuits constitute parallel-connected connections of the second signal route to ground. The resonant circuits are electrically or magnetically coupled to one another and each comprise at least one tunable impedance element.

This RF filter circuit has a filter topology having intrinsic poles in the transfer characteristic. Said poles could then be used to suppress power spikes of undesired signals, e.g. harmonic or intermodulation products, in a targeted manner. The relative position of the poles in relation to the center frequency further determines the edge steepness, such that the edge steepness can be influenced, e.g. increased, by the positioning of the poles.

Furthermore, this topology enables a good adjustability of the bandwidth and of the center frequencies if the corresponding filter should be used as a bandpass filter. The circuitry outlay is low compared with the possible selection. The degree of complexity is relatively low and the outlay required for driving the filter is likewise low. This topology is particularly well suited to being interconnected with a port having a connection impedance having vanishing reactance.

Besides the good adjustability of the frequencies of the passband edges, a high edge steepness is additionally obtained.

All types of electrical circuits which can be excited to oscillation are appropriate as resonant circuits. They include e.g. LC circuits, circuits having electroacoustic resonators, ceramic resonators or so-called cavity resonators, such as are known e.g. from the paper “Analytical Modeling of Highly Loaded Evanescent-mode Cavity Resonators for Widely Tunable High-Q Filter Applications” by H. Joshi, H. H. Sigmarsson and W. J. Chappell.

It is possible for the impedance element in the first signal route to have a quality factor Q≦200. The resonant circuits arranged in the signal route can have in each case a quality factor Q>100. The resonant circuits can have a quality factor Q≦200 by means of coupling elements, e.g. coupled inductive elements, or by means of capacitive elements, a respective electrode of which is assigned to a resonant circuit.

The quality factor Q (also called Q factor) here is a measure of the damping of an oscillatory system. In this case, the value of the quality factor Q is all the higher, the lower the damping. In this case, a quality factor Q is assigned both for a resonant circuit and for individual circuit elements such as capacitive elements or inductive elements.

The RF filter circuit may in each case comprise a tunable capacitive element in each of the resonant circuits. Interconnected directly with the RF filter circuit, further tunable capacitive elements can be used for impedance matching.

The value of the capacitance of the capacitive element can be adjusted in order to tune the resonant frequency of the resonant circuit. The tuning of all the resonant circuits of the RF filter circuit then makes it possible to adjust the bandwidth of a bandpass filter, in the form of which the filter circuit can be realized, and the frequency position of the center frequency.

As an alternative thereto, the resonant circuits can also in each case comprise a tunable inductive element in order to adjust the resonant frequencies of the resonant circuits. However, since the realization of a tunable capacitive element is generally simpler, the use of a tunable capacitive element is preferred. In this case, the tunable capacitive elements can be realized as adjustable MEMS capacitances, as varactors or as capacitance banks comprising individually connectable or disconnectable capacitors.

The tunable capacitive elements can have a quality factor Q>100.

The RF filter circuit can be realized such that the ratio of the capacitance values of the tunable capacitive elements is constant if capacitive elements are used as tunable impedance elements. Otherwise the ratio of the inductance values of tunable inductive elements relative to one another can be constant.

The tunable RF filter circuit can in each case comprise oscillatory circuit sections in each of its resonant circuits. Said circuit sections can comprise an LC resonant circuit, a ceramic resonator, an MEMS resonator, an acoustic resonator, or a resonator with a waveguiding arrangement integrated in a substrate.

The use of LC resonant circuits in the resonant circuits enables a simple and cost-effective construction in conjunction with—as a result of the chosen topology—at the same time good electrical properties of the filter. The use of a ceramic resonator, that is to say of a ceramic body, in which recesses with metalized surfaces are structured likewise enables good electrical properties, but in return requires relatively large dimensions. The use of an MEMS (MEMS=Micro Electro Mechanical System) resonator means the use of a resonator in which material is excitable to mechanical oscillation. One example of an MEMS resonator is an acoustic resonator in which a—generally piezoelectric—material is excitable to perform acoustic oscillations.

If the resonator furthermore comprises structured elements which can be used to adjust the wave propagation in a targeted manner, an integrated waveguiding arrangement and thus a resonator with a waveguiding arrangement integrated in a substrate is obtained.

In particular the resonant circuits in which MEMS resonators operate afford good electrical properties in conjunction with at the same time relatively small structural sizes, since the speed of sound is orders of magnitude lower than the speed at which an electrical signal propagates in a conductor.

If the resonant circuits are equipped with oscillatory LC resonant circuits, then an inductive element in the resonant circuit interconnected with the input or output can have an inductance of approximately 1 nH. The capacitance of a tunable capacitive element can be adjustable in a value range around the capacitance value 1 pF.

The inductances of the inductive elements of the “inner” resonant circuits can be 2 nH. The capacitance of the tunable capacitive elements of the “inner” resonant circuits can be adjustable in a capacitance range around 2 pF.

Capacitive elements which bring about a coupling of resonant circuits can have a capacitance of between 10 fF and 100 pF. Inductive elements which bring about a coupling of resonant circuits can have an inductance of between 1 nH and 300 nF.

Inductive elements in the resonant circuits can have inductances of between 0.1 nH and 50 nH. Capacitive elements in the resonant circuits can have capacitances of between 0.1 pF and 100 pF.

The tunable RF filter circuit can comprise N=4 resonant circuits in the second signal path which are arranged one after another. The impedance element in the first signal route can be an inductive element. The signal path can comprise a respective capacitive element on the input side and on the output side. A capacitive element can thus be interconnected between the input of the signal path and the location at which the signal path splits into the first signal route and the second signal route. Likewise, a capacitive element can be arranged between the output and the location at which the two signal routes recombine.

The tunable RF filter circuit can be configured such that the “outer” resonant circuits, that is to say the resonant circuits which enclose or encompass the remaining resonant circuit(s), have a higher quality factor Q than the enclosed “inner” resonant circuits. In this case, the “outer” resonant circuits are those resonant circuits which are interconnected the nearest with the input or the output. It is generally more important, however, that the resonant circuits have a higher quality factor Q than the coupling elements.

The tunable RF filter circuit can be configured in particular such that the resonant circuits have a higher quality factor Q than the coupling elements used to couple the resonant circuits.

It has been discovered that specific circuit elements of the tunable RF filter circuit react particularly sensitively toward a variation of the quality factor. In contrast thereto, there are circuit elements whose quality factor has virtually no effect on the electrical properties of the filter. In this case, the electrical properties of the filter circuit depend very greatly on the quality factors of the circuit elements in the resonant circuits. In this case, the quality factors of the coupling elements which bring about the electromagnetic coupling exhibit significantly less influence on the electrical properties of the filter circuit.

This insight can be used to realize insensitive circuit parts by relatively inexpensive components, while the expensive and complex circuit elements having a high quality factor are to be provided only for the sensitive regions of the tunable filter circuit.

Since the less critical circuit regions can thus also be realized by impedance elements of relatively compact construction, the trend toward miniaturization can be followed virtually without losses of quality.

The tunable RF filter circuit can have transfer poles. That is to say that there are frequencies at which the transfer function of the filter circuit has a pole and thus damps signals having precisely these frequency components particularly effectively.

The tunable circuit topology specified thus differs from known tunable circuit topologies in that intrinsic poles exist which, in the known circuit topologies without these intrinsic poles, have to be added by the addition of further impedance elements—generally having a high quality factor.

The tunable RF filter circuit can be used in a transmitting filter and/or a receiving filter, e.g. of a non-wired communication device. Particularly the use in a communication device provided for being able to operate a multiplicity of frequency bands is advantageous. This is because an individual tunable filter can replace two or more filters having non-variable passbands.

The individual circuit components of the RF filter circuit can be jointly integrated in a package. Such a package can have a substrate which serves as a carrier for discrete components and additionally has at least one wiring plane. On the top side of the substrate, in a first component position, a semiconductor component can be mounted and electrically connected to the first wiring plane. The semiconductor component has tunable passive components having a high quality factor, which enable a frequency tuning of the filter.

Situated above the dielectric layer is a second component position, in which discrete passive components interconnected with the semiconductor component are arranged.

A filter that is tunable with regard to its cut-off frequency or its frequency band is realized from the tunable passive components, the discrete passive components and, if appropriate, further components. Such a filter can be embodied as a bandpass filter. However, it is also possible to embody the filter as a high-pass filter or as a low-pass filter. A band-stop filter can also be realized as a tunable filter.

The tunable passive components in the semiconductor component can be fabricated in an integrated fashion and interconnected with one another in an integrated fashion. In the semiconductor component, these components can be distributed over the area of the semiconductor component.

If components having a quality factor of at least 100 are chosen for the components having a high quality factor, that is to say for the discrete components and the tunable components having a high quality factor, then filters having a tuning factor of up to 4:1 can be obtained. Converted to frequency, this corresponds to a factor of 2 between the lowest and highest cut-off frequency or frequency range to be set. For higher frequencies, higher quality factors can be realized in a simpler manner. Use in a frequency range of between 400 MHz and 8 GHz is possible.

It is possible for the circuit to be interconnected in a receiving or transmitting path of a mobile communication device.

Precisely because the circuit enables a good frequency-tuning and at the same time a good impedance matching over a wide impedance range, it is particularly suitable for interconnecting a power amplifier having a low output impedance in a transmitting path or a low noise amplifier having a high output impedance in a receiving path with an antenna connection in a front-end circuit of the communication device.

It is possible for the circuit to be contained not just in one signal path of a communication device, but rather to perform corresponding impedance matching and filter functions in different signal paths of a communication device. In this regard, two or more corresponding circuits can be interconnected in a mobile communication device and at least two of the tunable RF filter circuits together can form a duplexer.

It is possible for the circuit to comprise two reactance elimination circuit sections and a tunable RF filter circuit therebetween, such that the two reactance elimination circuit sections together enable a reactance elimination and each of the sections contributes its portion thereto. The reactance elimination can thus be better coordinated with requirements of the filter circuit with regard to impedance matching.

In particular, it is therefore also possible for an amplifier circuit to comprise a combined impedance matching and RF filter circuit as described above which interconnects an antenna connection either with a power amplifier or with a low noise amplifier. Here, in the case of interconnection with a power amplifier, the power amplifier is interconnected with the signal input of the circuit.

In the case of the low noise amplifier, the low noise amplifier is interconnected with the signal output of the combined impedance matching and filter circuit.

It is thus possible for the reactance elimination circuit always to be arranged between an amplifier and the tunable RF filter circuit.

The circuit or an amplifier circuit is explained in greater detail below on the basis of schematic exemplary embodiments and equivalent circuit diagrams.

In the figures:

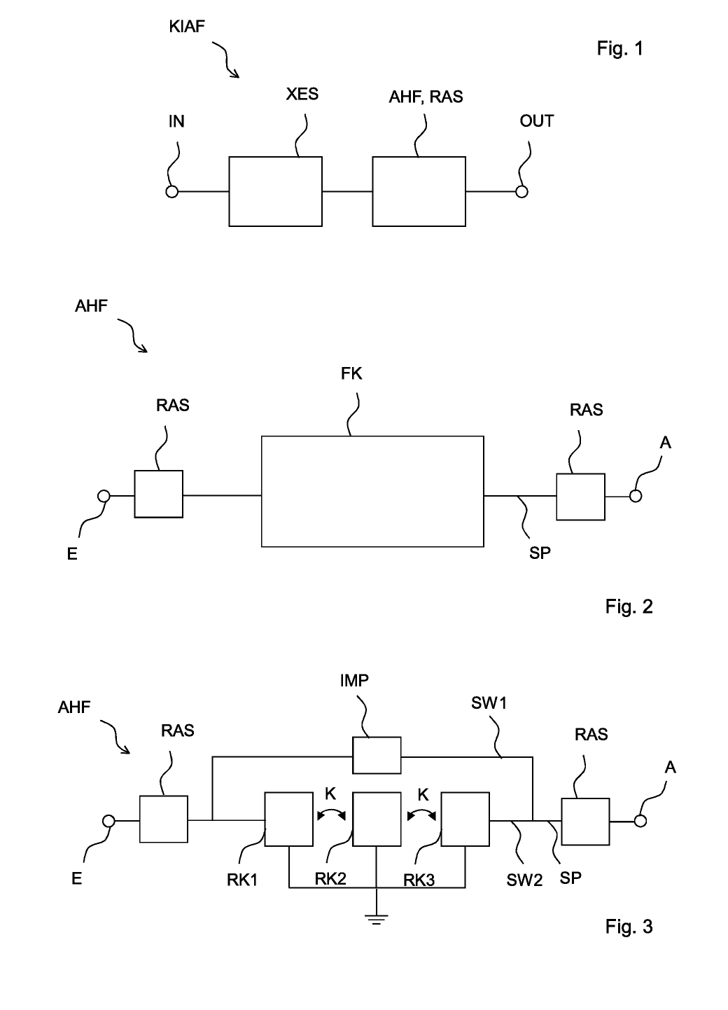

FIG. 1: shows the reactance elimination circuit XES and the tunable RF filter circuit AHF, which together form the essential components of the combined impedance matching and RF filter circuits KIAF,

FIG. 2: shows one possible arrangement of two reactance elimination circuits in the tunable RF filter circuit,

FIG. 3: shows one possible circuit topology of the tunable RF filter circuit,

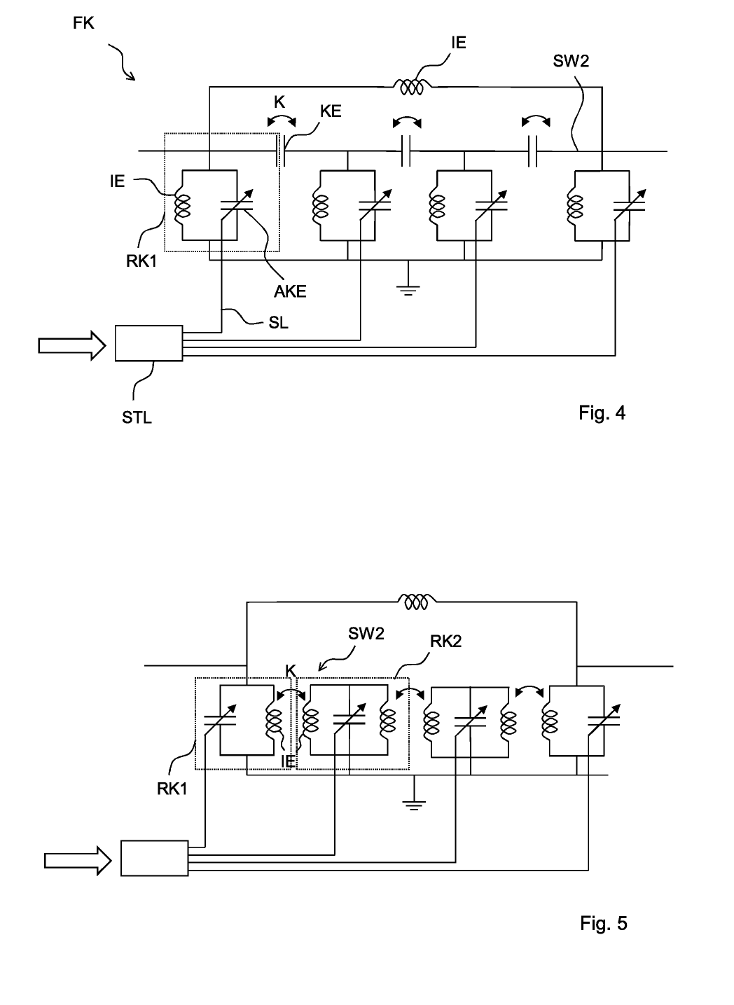

FIG. 4: shows more extensive details of one possible configuration of the tunable RF filter circuit,

FIG. 5: shows details of an alternative configuration of the tunable RF filter circuit,

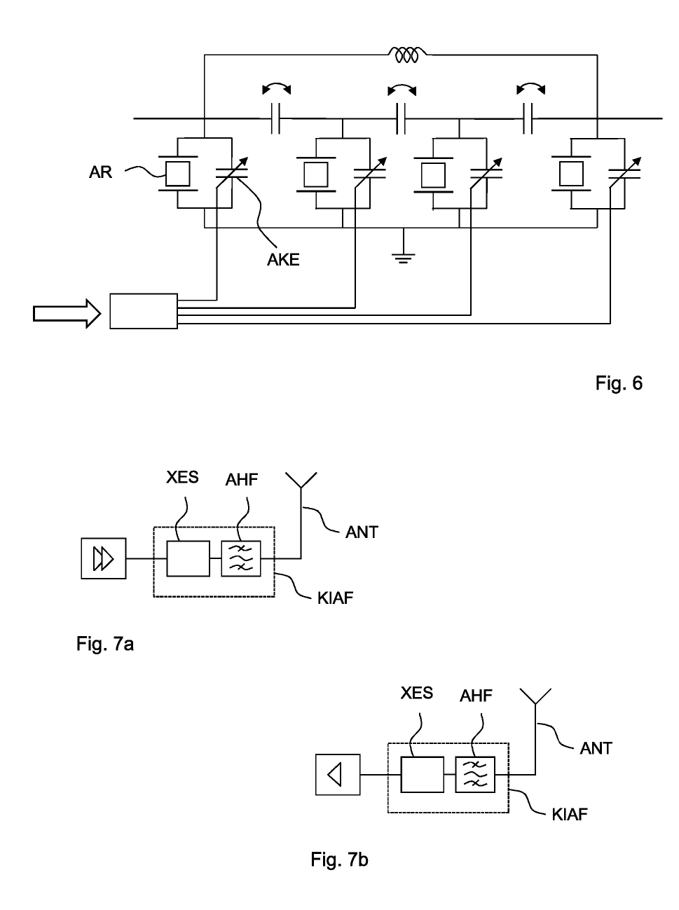

FIG. 6: shows details of a tunable RF filter circuit comprising acoustic, ceramic or MEMS-based resonators,

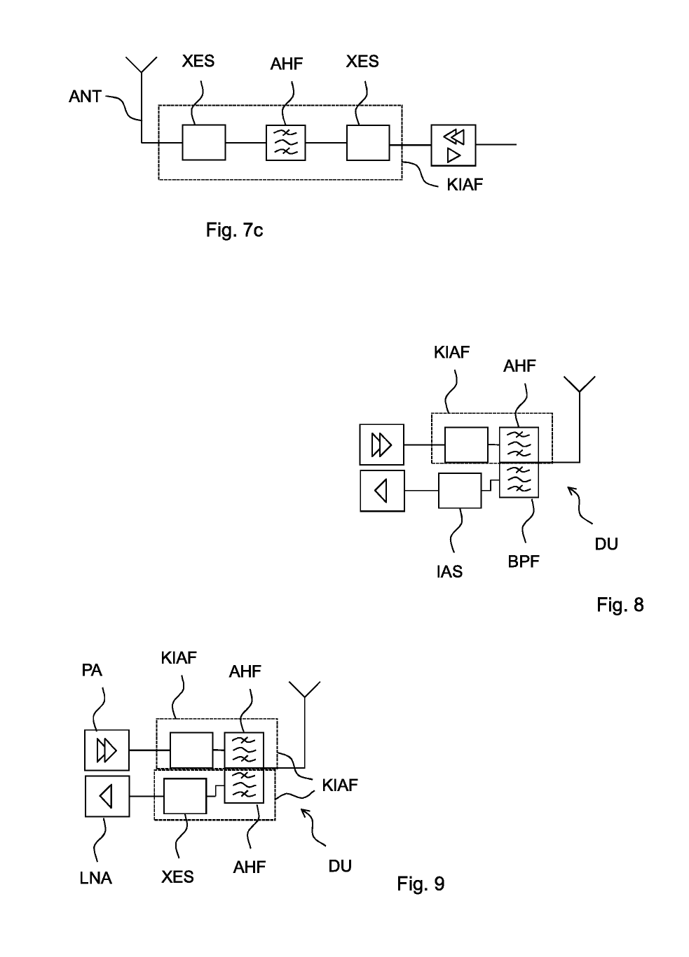

FIG. 7a: shows one possible use of the circuit in a mobile communication device,

FIG. 7b: shows one possible use of the circuit in a receiving branch of a mobile communication device,

FIG. 7c: shows one possible use of the circuit comprising two reactance elimination circuits,

FIG. 8: shows one possible use of the circuit in a communication device comprising further circuit components,

FIG. 9: shows a mobile communication device comprising at least two of the circuits described.

FIG. 1 shows the two important circuit components of the combined impedance matching and RF filter circuit KIAF. A reactance elimination circuit XES and a frequency-tunable RF filter circuit AHF are interconnected between the signal input IN of the circuit and the signal output OUT of the circuit. A port of an external circuit environment, e.g. of an amplifier, which has a connection impedance Z=R+jX, can be connected to the signal input IN. In this case, R is the resistance, while X is the reactance. The reactance elimination circuit makes available at its output facing the signal output OUT an output impedance whose reactance X is substantially 0Ω. The impedance Z is thus substantially reduced to a real value having an absolute value around the value R.

The tunable RF filter circuit AHF is configured such that it can carry out a matching of the resistance R, without changing the value of the reactance X. The tunable RF filter circuit AHF thus comprises the functionality of a resistance matching circuit RAS.

At its signal output OUT the circuit KIAF thus makes available an RF signal corrected with regard to undesired signals by the filter effect of the tunable RF filter circuit. The signal is made available at a port with a connection impedance adjusted with regard to its reactance and its resistance such that signals can be forwarded without reflection to a circuit environment connected to the signal output OUT.

Since the matching of the reactance and of the resistance is carried out in different assemblies of the circuit, in particular the reactance elimination circuit XES can be simplified and optimized with regard to a low insertion loss such that the entire circuit operates with improved energy efficiency.

In a transmitting branch, the connection IN can be connected to a power amplifier and, in a receiving branch, the connection IN can be connected to a low noise amplifier. In this case, the designations IN and OUT are interchangeable insofar as they denote the signal input and signal output, respectively.

FIG. 2 shows one possible form of the tunable RF filter circuit AHF, in which a respective resistance matching circuit RAS is arranged both on the input side and on the output side. In this regard, the input-side resistance matching circuit RAS is arranged between the input E of the tunable RF filter circuit AHF and a filter core FK substantially responsible for the filter effect of the tunable RF filter circuit. The output-side resistance matching circuit RAS is arranged between the filter core FK and the output A of the tunable RF filter circuit AHF.

If two resistance matching circuits RAS exist in the tunable RF filter circuit AHF, then the matching of the resistance can be carried out in two stages. A single-stage matching is likewise possible; the input-side or the output-side resistance matching circuit can then be omitted.

However, it is also possible for the filter core FK itself to realize not only the filter effect but also additionally a resistance matching.

Via the input E of the tunable RF filter circuit, the latter can be interconnected with the reactance elimination circuit XES. The output A of the tunable RF filter circuit can correspond to the signal output OUT of the circuit. It is also possible for another resistance matching circuit RAS to be arranged between the output A of the tunable RF filter circuit in FIG. 3 and the signal output OUT in FIG. 1.

FIG. 3 shows an equivalent circuit diagram of one possible tunable RF filter circuit AHF, in which a signal path SP is arranged between an input E and an output A. In this case, the signal path SP comprises two parallel-connected partial sections, namely the first signal route SW1 and the second signal route SW2. An impedance element IMP is interconnected in the first signal route SW1. The impedance element IMP can be realized as a capacitive element or as an inductive element. The three resonant circuits RK1, RK2, RK3 are arranged one after another in the second signal route SW2. The resonant circuits are electrically or magnetically coupled and each comprise at least one tunable impedance element. Each of the three resonant circuits interconnects the second signal route with ground.

In this case, the first resonant circuit RK1 is coupled to the input E. In this case, the third resonant circuit RK3 is coupled to the output A. Those resonant circuits which are coupled to the input E or to the output A directly rather than via another resonant circuit constitute the so-called “outer” resonant circuits. These two outer resonant circuits thus enclose the other resonant circuit(s), which thus constitute “inner” resonant circuits.

In the equivalent circuit diagram in FIG. 3, therefore, the first resonant circuit RK1 and the third resonant circuit RK3 constitute the outer resonant circuits, while the second resonant circuit RK2 constitutes the (sole) inner resonant circuit.

The electrical and/or magnetic coupling of the resonant circuits is symbolized by the coupling designated by K. In this case, the first resonant circuit RK1 is electrically and/or magnetically coupled to the second resonant circuit RK2. The second resonant circuit RK2 is also coupled to the third resonant circuit RK3 besides the first resonant circuit RK1.

Via the coupling of the resonant circuits, an electrical signal can be forwarded from resonant circuit to resonant circuit, such that an RF signal can propagate in the second signal route SW2 as well.

FIG. 4 shows one possible equivalent circuit diagram of the tunable RF filter circuit in which the resonant circuits are realized as LC circuits. Each resonant circuit, shown here on the basis of the example of the first resonant circuit RK1—comprises a parallel connection of an inductive element IE and a tunable capacitive element AKE. The tunable capacitive element AKE in this case constitutes the tunable impedance element of the corresponding resonant circuit. Conversely, each resonant circuit could also comprise a tunable inductive element. The corresponding parallel-connected impedance element of the resonant circuit would then be a capacitive element.

The tunable capacitive element AKE is interconnected with a control logic STL. The control logic STL comprises circuit elements that can be used to receive a control signal of an external circuit environment. The control signal of the external circuit environment is interpreted and control signals are output to the individual tunable capacitive elements AKE via corresponding signal lines SL.

The electromagnetic coupling between the resonant circuits is realized by a capacitive coupling of capacitive elements KE as coupling elements. For this purpose, each resonant circuit essentially comprises an electrode of a capacitive element KE via which it is coupled to the adjacent resonant circuit or the adjacent resonant circuits. In this case, a coupling via capacitive elements KE essentially constitutes a capacitive electrical coupling. In this case, the quality factor Q of said capacitive elements is permitted to be lower than the quality factor Q of the elements used in the resonant circuits.

The input-side resonant circuit can comprise a tunable capacitive element whose capacitance is adjustable in a range around 34.34 pF. At the input of the tunable RF filter circuit, there may be present in the signal path in series a further tunable capacitive element (not shown), the capacitance of which is adjustable at least in a range of between 1 and 5 pF. In this regard, a good matching to impedances of between 5 and 50 ohms is possible. The range of the capacitance can also be chosen such that good matchings to customary impedances with a magnitude of 5, 10, 25, 50, 100, 200 and 500 ohms are possible. A 5 ohm matching is achieved in the case of 5 pF in the signal path and 34.34 pF relative to ground. A 50 ohm matching is achieved in the case of pF in the signal path and 38.81 pF relative to ground.

FIG. 5 shows the equivalent circuit diagram of the tunable RF filter circuit in which the coupling between the resonant circuits RK is effected inductively. In this case, each resonant circuit has at least one inductive element IE via which a coupling to another inductive element of the corresponding resonant circuit is effected. Since the first resonant circuit RK1 is only inductively coupled to the second resonant circuit RK2, the first resonant circuit RK1 needs only one inductive element IE1 for coupling. The second resonant circuit RK2 is inductively coupled both to the first resonant circuit RK1 and to the third resonant circuit and therefore requires two inductive elements.

Whether the resonant circuits are coupled inductively or capacitively is unimportant for the fact that RF signals can be transmitted, such that the series arrangement of resonant circuits constitutes the second signal route SW2.

The capacitive elements for coupling between the resonant circuits in FIG. 5 and the inductive elements for coupling the resonant circuits in FIG. 6 are in this case arranged and configured such that the correct degree of coupling is obtained. In this case, the degree of coupling can be set by the distance between the electrodes or the electrode area or the coil shape, coil size and coil distance.

In each case two inductively coupled inductive elements of adjacent resonant circuits here essentially form a transformer circuit.

FIG. 6 shows an equivalent circuit diagram of the tunable RF filter circuit in which the resonant circuits comprise an acoustic resonator AR besides a tunable capacitive element AKE. Acoustic resonators are distinguished by high quality factors and at the same time by small dimensions. However, since they cause comparatively high production costs and require measures for decoupling and for protection against interfering ambient conditions on account of their mechanical mode of operation, the use of LC components may be preferred. Other types of resonators such as ceramic resonators, disk resonators, cavity resonators, MEMS-based resonators and the like are likewise possible.

FIG. 7a shows one possible application of the circuit between an amplifier, e.g. a power amplifier, and an antenna connection of a mobile communication device, which is interconnected with an antenna ANT. The sudden change in impedance from the amplifier to the antenna is generally particularly large, but the splitting of the matching into a matching of the reactance and a matching of the resistance brings about a particularly good matching in conjunction with a relatively simple construction even with the use of a tunable filter.

FIG. 7b shows one possible application of the circuit between an amplifier, e.g. a low noise amplifier, and an antenna connection of a mobile communication device, which is interconnected with an antenna ANT.

FIG. 7c shows one possible application of the circuit between an amplifier and an antenna connection of a mobile communication device. The amplifier may be —depending on the direction of the RF signal—a power amplifier in a transmitting path or a low noise amplifier in a receiving path or both in a duplexed signal path. The task of eliminating the reactance is divided between two separate circuit segments. A first section of the reactance elimination circuit XES is interconnected between the antenna ANT and the tunable RF filter AHF and a second section of the reactance elimination circuit XES is interconnected between the tunable RF filter AHF and the antenna ANT. In this regard, the variability in the reduction of the reactance is increased.

FIG. 8 shows one possible application in which the tunable RF filter AHF is part of a duplexer DU. The tunable RF filter in this case constitutes a bandpass filter which, together with a further, if appropriate tunable, bandpass filter of a parallel signal path, ensures the filter effect in conjunction with good isolation of the duplexer.

FIG. 9 shows a double application of the circuit KIAF, which is used both in a transmitting path between a power amplifier PA and an antenna connection and in a reception signal between a low noise amplifier LNA and the antenna connection.

The circuit in this case is not restricted exclusively to the exemplary embodiments shown; circuits comprising further filters, resonant circuits or impedance matching sections are likewise encompassed. Uses other than the uses shown above in transmitting or receiving paths or in a duplexer are also possible.

### LIST OF REFERENCE SIGNS

A: Output of the tunable RF filter circuit
AHF: Tunable RF filter circuit
ANT: Antenna
DU: Duplexer
E: Signal input of the tunable RF filter circuit
FK: Filter core
IMP: Impedance element
IN: Signal input of the circuit
KIAF: Combined impedance matching and RF filter circuit, also referred to just as “circuit” for the sake of simplicity
LNA: Low noise amplifier
OUT: Signal output of the circuit
PA: Power amplifier
RAS: Resistance matching circuit
SP: Signal path
SW1, SW2: First, second signal route
XES: Reactance elimination circuit

1. A combined impedance matching and RF filter circuit, comprising
a signal input, a signal output,
a reactance elimination circuit between the signal input and the signal output,
a frequency-tunable RF filter circuit interconnected in series with the reactance elimination circuit between the signal input and the signal output,
wherein
the signal input and the signal output are provided for being interconnected with circuit components having different connection impedances,
the reactance elimination circuit makes available an output impedance without reactance,
the tunable RF filter circuit is suitable for carrying out a matching of the resistance with unchanged reactance.

2. The circuit according to claim 1, wherein the tunable RF filter circuit comprises a resistance matching circuit on the input or output side or the input and output side.

3. The circuit according to claim 1, wherein the tunable RF filter circuit comprises at least one of tunable capacitive or inductive elements for the frequency tuning.

4. The circuit according to claim 1, wherein the tunable RF filter circuit is constructed from passive circuit elements.

5. The circuit according to claim 1, wherein the reactance elimination circuit comprises at least one of capacitive or inductive elements.

6. The circuit according to claim 5, wherein the reactance elimination circuit comprises at least one of tunable capacitive or inductive elements for reducing the absolute value of the reactance.

7. The circuit according to claim 1, wherein the tunable RF filter circuit comprises a filter core
having a first impedance element in a first signal route and
having electromagnetically coupled impedance elements interconnected in series in a second signal route interconnected in parallel with the first signal route.

8. The circuit according to claim 1, which is interconnected in a receiving or transmitting path of a mobile communication device.

9. The circuit according to claim 1, which is interconnected together with a further circuit according to claim 1 in a mobile communication device, wherein the two tunable RF filter circuits together form a duplexer.

10. The circuit according to claim 1, comprising two reactance elimination circuits and a tunable RF filter circuit interconnected between the two reactance elimination circuits.

11. An amplifier circuit, comprising
a combined impedance matching and RF filter circuit according to claim 1,
an antenna connection, and
either a power amplifier interconnected with the signal input of the combined impedance matching and filter circuit, or a low noise amplifier interconnected with the signal output of the combined impedance matching and filter circuit,
wherein
the combined impedance matching and RF filter circuit are interconnected between the amplifier and the antenna connection.

12. A combined impedance matching and RF filter circuit, comprising
a signal input, a signal output,
a reactance elimination circuit between the signal input and the signal output,
a frequency-tunable RF filter circuit interconnected in series with the reactance elimination circuit between the signal input and the signal output,
wherein
the signal input and the signal output are provided for being interconnected with circuit components having different connection impedances,
the reactance elimination circuit makes available an output impedance without reactance,
the tunable RF filter circuit is suitable for carrying out a matching of the resistance with unchanged reactance
the tunable RF filter circuit comprises a filter core having a first impedance element in a first signal route and having electromagnetically coupled impedance elements interconnected in series in a second signal route, which is interconnected in parallel with the first signal route.

13. The circuit according to claim 2, wherein the tunable RF filter circuit comprises at least one of tunable capacitive or inductive elements for the frequency tuning or the reactance elimination circuit comprises at least one capacitive or inductive elements.

14. The circuit according to claim 2, wherein the tunable RF filter circuit comprises a filter core
having a first impedance element in a first signal route and
having electromagnetically coupled impedance elements interconnected in series in a second signal route interconnected in parallel with the first signal route.

15. The circuit according to claim 3, wherein the tunable RF filter circuit comprises a filter core
having a first impedance element in a first signal route and
having electromagnetically coupled impedance elements interconnected in series in a second signal route interconnected in parallel with the first signal route.

16. The circuit according to claim 2, comprising two reactance elimination circuits and a tunable RF filter circuit interconnected between the two reactance elimination circuits.

17. The circuit according to claim 3, comprising two reactance elimination circuits and a tunable RF filter circuit interconnected between the two reactance elimination circuits.

18. The circuit according to claim 3, wherein the tunable RF filter circuit comprises a resistance matching circuit on the input or output side or the input and output side, the circuit further comprising two reactance elimination circuits and a tunable RF filter circuit interconnected between the two reactance elimination circuits.
